(19) United States
(12) Patent Application Publication
(10) Pub. No.: US 2025/0142994 A1
(43) Pub. Date: May 1, 2025

(54) IMAGE SENSOR AND ELECTRONIC SYSTEM INCLUDING THE SAME

(71) Applicant: SAMSUNG ELECTRONICS CO., LTD., Suwon-si (KR)

(72) Inventors: Juhyeon BAEK, Suwon-si (KR); Dongchan Kim, Suwon-si (KR); Beomsuk Lee, Suwon-si (KR); Byoungho Kwon, Suwon-si (KR); Changkyu Lee, Suwon-si (KR); Hwiyoung Jeon, Suwon-si (KR)

(73) Assignee: SAMSUNG ELECTRONICS CO., LTD., Suwon-si (KR)

(21) Appl. No.: 18/750,406

(22) Filed: Jun. 21, 2024

(30) Foreign Application Priority Data
Oct. 25, 2023 (KR) 10-2023-0144171

(51) Int. Cl. H01L 27/146

(52) U.S. Cl. CPC H10F 39/8057; H10F 39/182; H10F 39/802

(57) ABSTRACT

An image sensor includes unit pixels respectively including photodiodes in a substrate having frontside and backside surfaces, a sensor array area including at least one isolation structure configured to isolate the unit pixels from each other and vertically penetrating the substrate, and a capacitor area arranged adjacent to the sensor array area in a horizontal direction parallel to the backside surface of the substrate and including at least one capacitor on the frontside surface of the substrate and at least one dummy isolation structure located adjacent to the at least one capacitor to vertically penetrate the substrate, wherein one end surface of each of the at least one capacitor and the at least one dummy isolation structure is coplanar with the backside surface of the substrate, and the at least one isolation structure and the at least one dummy isolation structure include a same material.

### CROSS-REFERENCE TO RELATED APPLICATION

This application is based on and claims priority to Korean Patent Application No. 10-2023-0144171, filed on Oct. 25, 2023, in the Korean Intellectual Property Office, the disclosure of which is incorporated by reference herein in its entirety.

### BACKGROUND

### 1. Field

The disclosure relates to an image sensor and an electronic system including the image sensor, and more particularly, to an image sensor which includes a sensor array area and a capacitor area, and an electronic system including the image sensor.

### 2. Description of Related Art

Along with the advance of the computer industry and the communication industry, image sensors, which capture images and convert the images into electrical signals, are used in various applications, such as digital cameras, camcorders, personal communication systems (PCSs), game consoles, security cameras, and medical micro-cameras. With the high integration of image sensors and the miniaturization of pixel size, the width of a sensing area defined by a device isolation structure has been gradually decreased to implement image sensors. Therefore, although the density of device isolation structures is high in sensor array areas including the device isolation structures, because there are no device isolation structures in peripheral circuit areas surrounding the sensor array areas, there is a relatively great difference in a polishing rate between the sensor array areas and the peripheral circuit areas when backside surfaces of substrates are planarized during the process of fabricating image sensors, and thus, process defects may be generated in subsequent photolithography processes.

### SUMMARY

Provided is an image sensor having a structure capable of suppressing process defects due to a step difference between a sensor array area and a capacitor area adjacent to the sensor array area out of a peripheral area around the sensor array area by minimizing the difference in polishing rate between the sensor array area and the capacitor area when a backside surface of a substrate is planarized during the process of fabricating an image sensor.

Further, provided is an electronic system including an image sensor that has a structure capable of suppressing process defects due to a step difference between a sensor array area and a capacitor area adjacent to the sensor array area out of a peripheral area around the sensor array area by minimizing the difference in polishing rate between the sensor array area and the capacitor area when a backside surface of a substrate is planarized during the process of fabricating an image sensor.

According to an aspect of the disclosure, an image sensor includes: a sensor array area comprising: a plurality of unit pixels each comprising a photodiode in a substrate, wherein the substrate comprises a frontside surface and a backside surface; and at least one isolation structure passing through the substrate in a vertical direction from the frontside surface to the backside surface, wherein the at least one isolation structure isolates the plurality of unit pixels from one another; and a capacitor area adjacent to the sensor array area, wherein the capacitor area comprises: at least one capacitor on the frontside surface; and at least one dummy isolation structure adjacent to the at least one capacitor, wherein the at least one dummy isolation structure passes through the substrate in the vertical direction, wherein one end surface of each of the at least one isolation structure and the at least one dummy isolation structure extends in a same plane as the backside surface, and wherein the at least one isolation structure and the at least one dummy isolation structure comprise a same material.

According to an aspect of the disclosure, an image sensor includes: a sensor array area comprising: a plurality of unit pixels each comprising a photodiode in a substrate, wherein the substrate comprises a frontside surface and a backside surface; and at least one isolation structure passing through the substrate in a vertical direction from the frontside surface to the backside surface, wherein the at least one isolation structure isolates the plurality of unit pixels from one another; a pad area surrounding the sensor array area and comprising a plurality of conductive pads; and a capacitor area between the sensor array area and the pad area, the capacitor area comprising: a plurality of capacitors on the frontside surface; and at least one dummy isolation structure passing through the substrate in the vertical direction between two adjacent capacitors from among the plurality of capacitors, wherein one end surface of each of the at least one isolation structure and the at least one dummy isolation structure extends in a same plane as the backside surface, and wherein the at least one isolation structure and the at least one dummy isolation structure comprise a same material.

According to an aspect of the disclosure, an image sensor includes: a first semiconductor chip comprising a logic area and a peripheral circuit area, wherein the logic area comprises a logic device and the peripheral circuit area comprises a peripheral circuit; and a second semiconductor chip stacked on the first semiconductor chip, wherein the second semiconductor chip comprises: a substrate comprising a frontside surface and a backside surface; a sensor array area comprising: a plurality of unit pixels each comprising a photodiode in the substrate; and a plurality of isolation structures passing through the substrate in a vertical direction from the frontside surface to the backside surface and isolating the plurality of unit pixels from one another; and a capacitor area surrounding the sensor array area and comprising: a plurality of capacitors on the frontside surface; and a plurality of dummy isolation structures arranged respectively adjacent to the plurality of capacitors and passing through the substrate in the vertical direction, wherein one end surface of each of the plurality of isolation structures and the plurality of dummy isolation structures extends in a same plane as the backside surface, and wherein the plurality of isolation structures and the plurality of dummy isolation structures comprise a same material.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a schematic exploded perspective view of an image sensor according to one or more embodiments;

FIG. 2 is a block diagram illustrating some components of an image sensor according to one or more embodiments;

FIG. 3 is a block diagram illustrating some components of an image sensor according to one or more embodiments;

FIG. 4 is an enlarged cross-sectional view illustrating a region EX1 of FIG. 3 when the region EX1 of FIG. 3 is rotated by as much as 180 degrees in an X-Y plane;

FIG. 5A is a plan view of a portion of a capacitor area of an image sensor according to one or more embodiments;

FIG. 5B is a cross-sectional view of a portion of the image sensor of FIG. 5A, taken along a line X2-X2′ of FIG. 5A;

FIG. 6 is a plan view illustrating an image sensor according to one or more embodiments;

FIG. 7 is a plan view illustrating an image sensor according to one or more embodiments;

FIGS. 8A, 8B, and 8C are cross-sectional views illustrating a sequence of processes of a method of fabricating an image sensor, according to one or more embodiments;

FIG. 9A is a block diagram of an electronic system according to one or more embodiments; and

FIG. 9B is a detailed block diagram of a camera module of the electronic system of FIG. 9A.

### DETAILED DESCRIPTION

Hereinafter, embodiments of the disclosure will be described in detail with reference to the accompanying drawings. Like components are denoted by like reference numerals throughout the specification, and repeated descriptions thereof are omitted.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms first, second, third, etc., may be used herein to describe various elements, the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

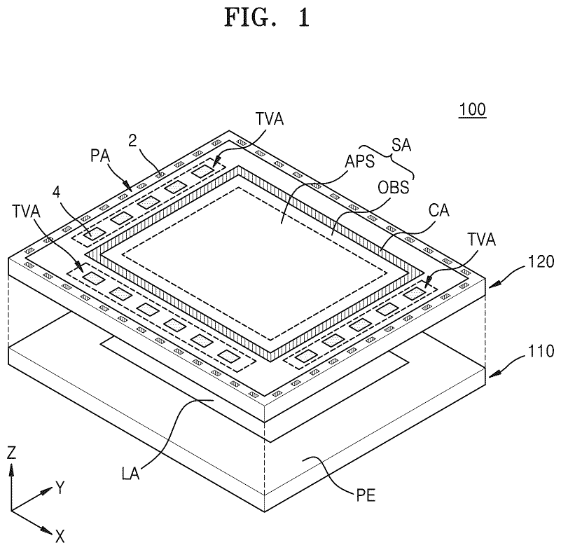

FIG. 1 is a schematic exploded perspective view of an image sensor 100 according to one or more embodiments.

Referring to FIG. 1, the image sensor 100 may include a first semiconductor chip 110 and a second semiconductor chip 120, which overlap each other in a vertical direction (e.g., the Z direction of FIG. 1). The first semiconductor chip 110 may include a logic chip, and the second semiconductor chip 120 may include a sensor chip.

The first semiconductor chip 110 may include a logic area LA including logic devices and a peripheral circuit area PE including peripheral circuits. The logic area LA may be surrounded by the peripheral circuit area PE.

The second semiconductor chip 120 may be stacked on the first semiconductor chip 110 to overlap the first semiconductor chip 110 in the vertical direction (the Z direction). The second semiconductor chip 120 may include a sensor array area SA, a capacitor area CA surrounding the sensor array area SA, a pad area PA surrounding the sensor array area SA and the capacitor area CA, and a plurality of through-via areas TVA between the capacitor area CA and the pad area PA. In the second semiconductor chip 120, the capacitor area CA, the plurality of through-via areas TVA, and the pad area PA may constitute a peripheral circuit area of the second semiconductor chip 120.

In the second semiconductor chip 120, the sensor array area SA may include an active pixel sensor area APS, which includes an active pixel for generating an active signal corresponding to wavelengths of light from outside the second semiconductor chip 120, and an optical black sensor area OBS, which includes an optical black pixel for generating an optical black signal by being blocked from light from outside the second semiconductor chip 120. A dummy pixel sensor may be arranged in an edge portion of the active pixel sensor area APS, which is adjacent to the optical black sensor area OBS.

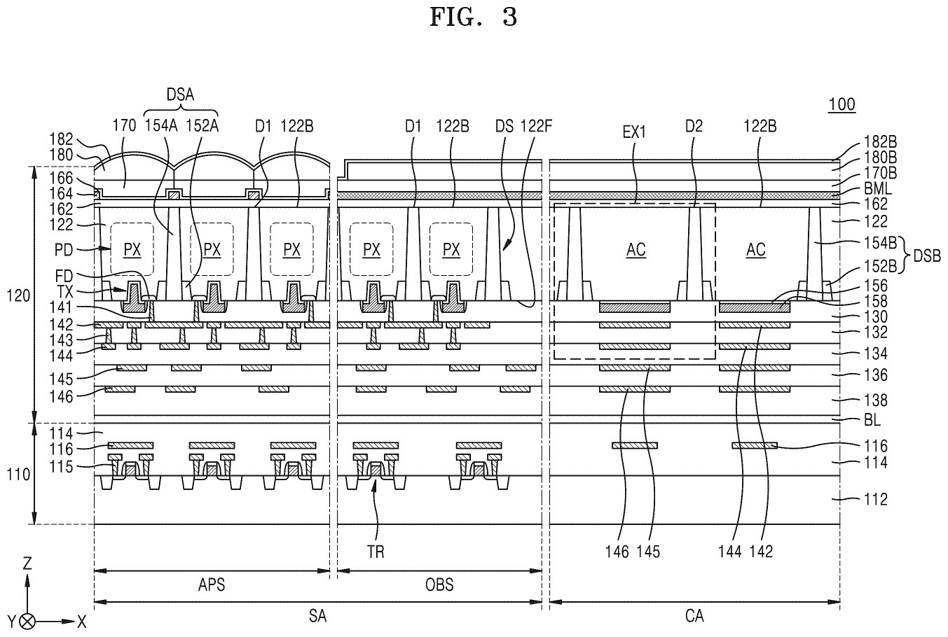

A plurality of capacitors (for example, a capacitor 158 of FIG. 3) may be arranged in the capacitor area CA of the second semiconductor chip 120. The sensor array area SA may be arranged in an area defined by the capacitor area CA. In the second semiconductor chip 120, the capacitor area CA may be arranged closer to the sensor array area SA than to the pad area PA. That is, in a horizontal direction (e.g., an X direction or a Y direction in FIG. 1), the distance between the capacitor area CA and the sensor array area SA may be less than the distance between the capacitor area CA and the pad area PA.

The capacitor area CA may be arranged adjacent to the optical black sensor area OBS and may be located apart from the active pixel sensor area APS with the optical black sensor area OBS therebetween to surround the active pixel sensor area APS and the optical black sensor area OBS. The capacitor area CA may have a shape of a rectangular ring surrounding the sensor array area SA, when viewed in a plane (the X-Y plane in FIG. 1). However, according to the disclosure, the planar shape of the capacitor area CA is not limited to the example shown in FIG. 1. For example, the capacitor area CA may be arranged locally or intermittently along the periphery of the optical black sensor area OBS to be adjacent to the optical black sensor area OBS.

A plurality of pads 2 may be arranged in the pad area PA of the second semiconductor chip 120. In one or more embodiments, the plurality of pads 2 may exchange electrical signals with an external device. In one or more embodiments, the plurality of pads 2 may transfer driving power, such as a power supply voltage or a ground voltage, which is supplied from outside the second semiconductor chip 120, to circuits in the second semiconductor chip 120.

A plurality of through-vias 4 may be arranged in each of the plurality of through-via areas TVA of the second semiconductor chip 120. Some of the plurality of through-vias 4 may respectively be connected to unit pixels in the sensor array area SA through wiring lines of the second semiconductor chip 120. Others of the plurality of through-vias 4 may respectively connect wiring lines of the first semiconductor chip 110 with wiring lines of the second semiconductor chip 120. Yet others of the plurality of through-vias 4 may respectively connect wiring lines of the first semiconductor chip 110 with logic devices that are included in the logic area LA of the second semiconductor chip 120.

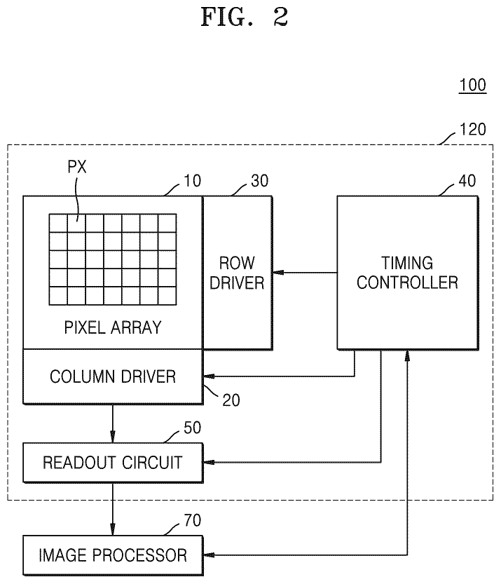

FIG. 2 is a block diagram illustrating some components of the image sensor 100 shown in FIG. 1.

Referring to FIGS. 1 and 2, the image sensor 100 may include a pixel array 10, which is arranged in the sensor array area SA, and circuits for controlling the pixel array 10. In one or more embodiments, the circuits for controlling the pixel array 10 may include a column driver 20, a row driver 30, a timing controller 40, and a readout circuit 50.

The image sensor 100 may operate according to a control command received from an image processor 70 and may convert light transferred from an external object into an electrical signal and output the electrical signal to the image processor 70. The image sensor 100 may include a complementary metal-oxide-semiconductor (CMOS) image sensor.

The pixel array 10 may include a plurality of unit pixels PX, which have a 2-dimensional array structure and are arranged in a matrix along a plurality of row lines and a plurality of column lines. As used herein, the term “unit pixel” may be simply referred to as a pixel.

Each of the plurality of unit pixels PX may include a photodiode. The photodiode may receive light transferred from the object and thus generate charges. The image sensor 100 may perform an autofocus function by using phase differences between pixel signals respectively generated by a plurality of photodiodes in the plurality of unit pixels PX. Each of the plurality of unit pixels PX may include a pixel circuit for generating a pixel signal from charges generated by the photodiode.

In one or more embodiments, the image sensor 100 may include an image sensor capable of performing a global shutter operation. For example, during the operation of the image sensor 100, all the unit pixels PX in the pixel array 10 may be simultaneously exposed to an optical signal provided from outside the image sensor 100, and thus, charges may be simultaneously stored in each of the plurality of unit pixels PX. In one or more embodiments, pixel signals due to the charges stored in each of the plurality of unit pixels PX may be sequentially output by row.

The column driver 20 may include a correlated double sampler (CDS), an analog-to-digital converter (ADC), and the like. The CDS may be connected with unit pixels PX, which are included in a row selected by a row select signal provided by the row driver 30, via column lines and may detect a reset voltage and a pixel voltage by performing correlated double sampling. The ADC may convert the reset voltage and the pixel voltage, which are detected by the CDS, into a digital signal and transfer the digital signal to the readout circuit 50.

The readout circuit 50 may include a latch or a buffer circuit, which may temporarily store the digital signal, an amplifier circuit, and the like and may generate image data by temporarily storing or amplifying the digital signal received from the column driver 20. Operation timings of the column driver 20, the row driver 30, and the readout circuit 50 may be determined by the timing controller 40, and the timing controller 40 may be operated by a control command transmitted by the image processor 70.

The image processor 70 may perform signal processing on the image data, which is output by the readout circuit 50, and output the processed image data to a display device or store the processed image data in a storage device, such as memory. When the image sensor 100 is mounted on an autonomous vehicle, the image processor 70 may perform signal processing on the image data and transmit the processed image data to a main controller for controlling the autonomous vehicle, or the like.

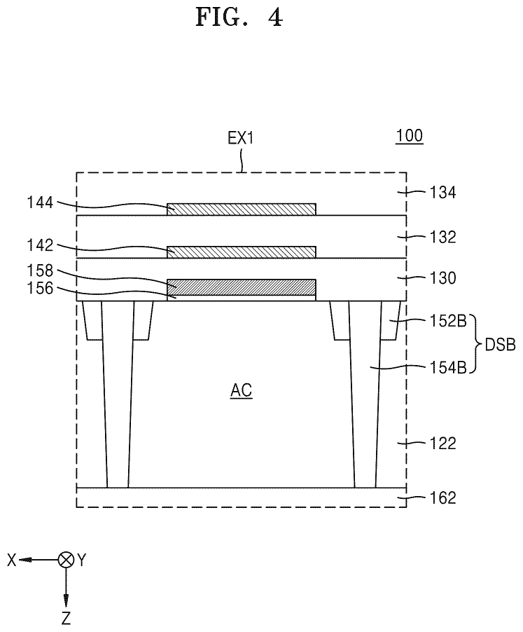

FIG. 3 is a block diagram illustrating some components of the image sensor 100 shown in FIG. 1. FIG. 4 is an enlarged cross-sectional view illustrating a region EX1 of FIG. 3 when the region EX1 of FIG. 3 is rotated by as much as 180 degrees in the X-Y plane.

Referring to FIGS. 1, 3, and 4, the image sensor 100 may include a second semiconductor chip 120 bonded onto the first semiconductor chip 110 by using a bonding layer BL. The second semiconductor chip 120 may include an active pixel area APS, the optical black sensor area OBS, and the capacitor area CA, which are sequentially arranged in the stated order in a first horizontal direction (the X direction). The active pixel area APS and the optical black sensor area OBS may constitute the sensor array area SA.

A plurality of unit pixels PX may be arranged in each of the active pixel area APS and the optical black sensor area OBS. Active pixels for generating active signals corresponding to wavelengths of light from outside the image sensor 100 may be arranged in the active pixel area APS. Optical black pixels, which are blocked from light from outside the image sensor 100 and generate optical black signals, may be arranged in the optical black sensor area OBS.

The optical black sensor area OBS may be formed along the periphery of the active pixel area APS. The active pixel area APS and the optical black sensor area OBS may constitute a sensor array area. In one or more embodiments, dummy unit pixels may be arranged in the optical black sensor area OBS. The dummy unit pixels may be pixels not generating active signals.

The image sensor 100 may include a substrate 122. The substrate 122 may include a semiconductor layer. In one or more embodiments, the substrate 122 may include a semiconductor layer doped with a P-type impurity. For example, the substrate 122 may include a semiconductor layer including Si, Ge, SiGe, a Group II-VI compound semiconductor, a Group III-V compound semiconductor, or a combination thereof. In one or more embodiments, the substrate 122 may include a P-type epitaxial semiconductor layer that is epitaxially grown on a P-type bulk silicon substrate. The substrate 122 may have a frontside surface 122F and a backside surface 122B, which are opposite to each other.

In the active pixel area APS and the optical black sensor area OBS, each of the plurality of unit pixels PX may include a photodiode PD, a floating diffusion region FD, and a transfer transistor TX. The photodiode PD and the floating diffusion region FD may be arranged in the substrate 122. The photodiode PD may generate charges in proportion to the amount of light incident from outside the image sensor 100. The charges generated as such may be accumulated in the photodiode PD, and the charges accumulated in the photodiode PD may be transmitted to the floating diffusion region FD. The charges transmitted to the floating diffusion region FD may be applied to a source follower gate, which is included in a unit pixel PX. One end of the transfer transistor TX may be connected to the photodiode PD, and another end of the transfer transistor TX may be connected to the floating diffusion region FD. The transfer transistor TX may transmit the charges generated by the photodiode PD to the floating diffusion region FD. The transfer transistor TX may include a transmission gate, a gate insulating film, and a gate spacer. The transmission gate may include a portion buried in the substrate 122. The gate insulating film may be arranged between the transmission gate and the substrate 122. The gate spacer may cover both sidewalls of the transmission gate.

A plurality of isolation structures DSA, which are configured to isolate the plurality of unit pixels PX from each other, may be arranged in each of the active pixel area APS and the optical black sensor area OBS. In one or more embodiments, at least some of the plurality of isolation structures DSA, which are shown in the active pixel area APS and the optical black sensor area OBS in FIG. 3, may have structures connected to each other. The plurality of isolation structures DSA may pass through the substrate 122 in the vertical direction (the Z direction). Herein, the vertical direction (the Z direction) may refer to a direction that is perpendicular to the backside surface 122B of the substrate 122.

The capacitor area CA may be adjacent to the sensor array area SA in a horizontal direction that is parallel to the backside surface 122B of the substrate 122, for example, the first horizontal direction (the X direction) and the second horizontal direction (the Y direction). In the capacitor area CA, a plurality of capacitors 158 and a plurality of dummy isolation structures DSB may be arranged. Each of the plurality of capacitors 158 may be arranged on the frontside surface 122F of the substrate 122 in an active region AC of the substrate 122. The plurality of dummy isolation structures DSB may be located respectively adjacent to the plurality of capacitors 158 to pass through the substrate 122 in the vertical direction (the Z direction).

In the capacitor area CA, an insulating film 156 may be arranged between the frontside surface 122F of the substrate 122 and a capacitor 158. In one or more embodiments, the capacitor 158 may include a doped polysilicon film. The insulating film 156 may include a silicon oxide film. However, the respective constituent materials of the capacitor 158 and the insulating film 156 are not limited to the examples set forth above. A structure of each of the plurality of capacitors 158 is not limited to the structure shown in FIG. 3. For example, each of the plurality of capacitors 158 in the capacitor area CA may include a metal-oxide-semiconductor (MOS)-structured capacitor or a metal-insulator-metal (MIM)-structured capacitor.

An end surface D1 of each of the plurality of isolation structures DSA in the sensor array area SA and an end surface D2 of each of the plurality of dummy isolation structures DSB in the capacitor area CA may extend in the same plane as the backside surface 122B of the substrate 122. The plurality of isolation structures DSA in the sensor array area SA and the plurality of dummy isolation structures DSB in the capacitor area CA may include the same material.

Each of the plurality of isolation structures DSA in the sensor array area SA may include a local device isolation film 152A and a main device isolation film 154A. The main device isolation film 154A may pass through the substrate 122 in the vertical direction (the Z direction) from the frontside surface 122F to the backside surface 122B of the substrate 122. The local device isolation film 152A may pass through only a portion of the substrate 122 in the vertical direction (the Z direction) from the frontside surface 122F of the substrate 122 and may cover a portion of a sidewall of the main device isolation film 154A, which is adjacent to the frontside surface 122F of the substrate 122.

Each of the plurality of dummy isolation structures DSB in the capacitor area CA may include a local device isolation film 152B and a main device isolation film 154B. The main device isolation film 154B may pass through the substrate 122 in the vertical direction (the Z direction) from the frontside surface 122F to the backside surface 122B of the substrate 122. The local device isolation film 152B may pass through only a portion of the substrate 122 in the vertical direction (the Z direction) from the frontside surface 122F of the substrate 122 and may cover a portion of a sidewall of the main device isolation film 154B, which is adjacent to the frontside surface 122F of the substrate 122.

In the plurality of isolation structures DSA in the sensor array area SA and the plurality of dummy isolation structures DSB in the capacitor area CA, the width of each of the main device isolation films 154A and 154B may gradually decrease toward the backside surface 122B of the substrate 122 from the frontside surface 122F of the substrate 122.

Each of the local device isolation films 152A and 152B and the main device isolation films 154A and 154B may include, but is not limited to, silicon oxide, silicon nitride, SiCN, SiON, SiOC, polysilicon, a metal, a metal nitride, a metal oxide, borosilicate glass (BSG), phosphosilicate glass (PSG), borophosphosilicate glass (BPSG), plasma-enhanced tetraethyl orthosilicate (PE-TEOS), fluoride silicate glass (FSG), carbon-doped silicon oxide (CDO), organosilicate glass (OSG), air, or a combination thereof. As used herein, the term “air” may refer to the atmosphere or to other gases that may be present during a fabrication process. When at least one of the local device isolation films 152A and 152B and the main device isolation films 154A and 154B includes a metal, the metal may include tungsten (W), copper (Cu), or a combination thereof. When at least one of the local device isolation films 152A and 152B and the main device isolation films 154A and 154B includes a metal nitride, the metal nitride may include TiN, TaN, or a combination thereof. When at least one of the local device isolation films 152A and 152B and the main device isolation films 154A and 154B includes a metal oxide, the metal oxide may include indium tin oxide (ITO), aluminum oxide (Al₂O₃), or a combination thereof.

In one or more embodiments, at least one of the local device isolation films 152A and 152B and the main device isolation films 154A and 154B may further include a silicon region doped with a P+ type impurity. The silicon region doped with a P+ type impurity may reduce dark current in the unit pixel PX and thus improve the quality of the image sensor 100.

In one or more embodiments, the density of the plurality of isolation structures DSA in the sensor array area SA may be equal or similar to the density of the plurality of dummy isolation structures DSB in the capacitor area CA. In one or more embodiments, the density of the plurality of isolation structures DSA in the sensor array area SA may be different from the density of the plurality of dummy isolation structures DSB in the capacitor area CA. In an example, the density of the plurality of dummy isolation structures DSB in the capacitor area CA may be less than the density of the plurality of isolation structures DSA in the sensor array area SA. In another example, the density of the plurality of dummy isolation structures DSB in the capacitor area CA may be greater than the density of the plurality of isolation structures DSA in the sensor array area SA.

The image sensor 100 may include a backside insulating film 162 covering the backside surface 122B of the substrate 122, a plurality of grid patterns 164 arranged on the backside insulating film 162 in the active pixel sensor area APS, a plurality of color filters 170 arranged over the backside insulating film 162 in the active pixel sensor area APS, and a plurality of microlenses 180 arranged in the active pixel sensor area APS to respectively cover the plurality of color filters 170.

In one or more embodiments, the backside insulating film 162 may include, but is not limited to, a silicon oxide film, a silicon nitride film, a silicon oxynitride film, an aluminum oxide film, a hafnium oxide film, or a combination thereof. The backside insulating film 162 may function as an anti-reflective film. The backside insulating film 162 may prevent the reflection of light incident on the substrate 122 from outside the image sensor 100 and thus improve the light-harvesting efficiency of the photodiode PD. In addition, the backside insulating film 162 may have a planarized surface. Because the plurality of color filters 170 and the plurality of microlenses 180 are arranged on or over the planarized surface of the backside insulating film 162, the respective heights of the plurality of color filters 170 and the plurality of microlenses 180 may be uniform.

Each of the plurality of color filters 170 may be arranged over the backside insulating film 162 to correspond to a respective unit pixel PX. The plurality of color filters 170 may respectively include various color filters depending on the unit pixel PX. In one or more embodiments, the plurality of color filters 170 may be arranged in a Bayer pattern including a red filter, a green filter, and a blue filter. In one or more embodiments, the plurality of color filters 170 may include a yellow filter, a magenta filter, and a cyan filter and may further include a white filter.

A grid pattern 164 may include a material having a refractive index which is lower than that of silicon (Si). In one or more embodiments, the grid pattern 164 may include, but is not limited to, a silicon oxide film, an aluminum oxide film, a tantalum oxide film, or a combination thereof.

In the active pixel sensor area APS, a first protective film 166 may be arranged between the backside insulating film 162 and the plurality of color filters 170 and between the plurality of grid patterns 164 and the plurality of color filters 170. The first protective film 166 may conformally cover the upper surface of the backside insulating film 162 and the side surface and the upper surface of the grid pattern 164. The first protective film 166 may protect the backside insulating film 162 and the grid pattern 164 such that the backside insulating film 162 and the grid pattern 164 are not damaged. The first protective film 166 may include, but is not limited to, an aluminum oxide film.

A second protective film 182 may be formed on a microlens 180. The second protective film 182 may conformally cover the surface of the microlens 180. The second protective film 182 may protect the microlens 180 from external impact and may improve the light concentration capability of the microlens 180. In one or more embodiments, the second protective film 182 may include, but is not limited to, a silicon oxide film, a titanium oxide film, a zirconium oxide film, a hafnium oxide film, or a combination thereof.

A wiring structure may be arranged on the frontside surface 122F of the substrate 122. The wiring structure may include a plurality of interlayer dielectrics 130, 132, 134, 136, and 138, which cover a plurality of transfer transistors TX, and a plurality of via contacts 141 and 143 and a plurality of wiring layers 142, 144, 145, and 146, which are covered by the plurality of interlayer dielectrics 130, 132, 134, 136, and 138. Some of the plurality of via contacts 141 and 143 may electrically connect the floating diffusion region FD with the wiring layers 142, 144, 145, and 146. Some wiring layers 142, 144, 145, and 146, which are arranged in the capacitor area CA, from among the plurality of wiring layers 142, 144, 145, and 146 may be arranged to overlap the capacitor 158 in the vertical direction (the Z direction).

The plurality of interlayer dielectrics 130, 132, 134, 136, and 138 and the plurality of wiring layers 142, 144, 145, and 146 are not limited to the example shown in FIG. 3 in terms of the number of layers and the arrangement of each thereof, and various modifications and changes may be made thereto, as needed. The plurality of wiring layers 142, 144, 145, and 146 may include conductive lines respectively connected to a plurality of transistors, which are each electrically connected with the photodiode PD. An electrical signal converted by the photodiode PD may undergo signal processing via the plurality of wiring layers 142, 144, 145, and 146. In one or more embodiments, each of the plurality of interlayer dielectrics 130, 132, 134, 136, and 138 may include, but is not limited to, a silicon oxide film, a silicon nitride film, a silicon oxynitride film, a low-K film having a dielectric constant that is lower than that of a silicon oxide film, or a combination thereof. In one or more embodiments, each of the plurality of via contacts 141 and 143 and the plurality of wiring layers 142, 144, 145, and 146 may include, but is not limited to, tungsten (W), copper (Cu), aluminum (Al), gold (Au), silver (Ag), or a combination thereof.

The first semiconductor chip 110 may include a logic substrate 112 and a plurality of transistors TR on the logic substrate 112. The plurality of transistors TR may constitute a logic circuit. In one or more embodiments, the plurality of transistors TR may constitute a circuit for controlling the transistors of the semiconductor chip 120.

An interlayer dielectric 114, which covers the plurality of transistors TR, and a plurality of via contacts 115 and a plurality of wiring layers 116, which are covered by the interlayer dielectric 114, may be arranged on or over the logic substrate 112. The plurality of transistors TR may be electrically connected with the plurality of wiring layers 116 via the plurality of via contacts 115, respectively. Some wiring layers 116, which vertically overlap the capacitor area CA, from among the plurality of wiring layers 116, may be arranged to overlap the capacitor 158 in the vertical direction (the Z direction). The interlayer dielectric 114 may include, but is not limited to, a silicon oxide film, a silicon nitride film, a silicon oxynitride film, a low-K film having a dielectric constant that is lower than that of a silicon oxide film, or a combination thereof. Each of the plurality of via contacts 115 and the plurality of wiring layers 116 may include, but is not limited to, tungsten (W), copper (Cu), aluminum (Al), gold (Au), silver (Ag), or a combination thereof.

In the optical black sensor area OBS and the capacitor area CA, a backside metal layer BML may be arranged over the backside surface 122B of the substrate 122. The backside metal layer BML may be separated from the backside surface 122B of the substrate 122 with the backside insulating film 162 therebetween. The backside metal layer BML may cut off light that is incident on the optical black sensor area OBS. In one or more embodiments, the backside metal layer BML may include, but is not limited to, titanium (Ti), titanium nitride (TiN), tungsten (W), or a combination thereof.

In the optical black sensor area OBS and the capacitor area CA, a color filter 170B may be arranged on the backside metal layer BML. In one or more embodiments, the color filter 170B may include, but is not limited to, a blue filter.

In the optical black sensor area OBS and the capacitor area CA, the color filter 170B may be covered by a third protective film 180B. The third protective film 180B may include a light-transmissive resin. In one or more embodiments, the third protective film 180B may include the same material as the constituent material of the microlens 180. The third protective film 180B may be covered by a fourth protective film 182B. The fourth protective film 182B may have substantially the same configuration as the second protective film 182 described above as being arranged in the active pixel sensor area APS.

The image sensor 100 described with reference to FIGS. 1 to 4 includes the capacitor area CA, which is located adjacent to the sensor array area SA to surround at least a portion of the sensor array area SA, and the plurality of dummy isolation structures DSB, which are each located adjacent to the capacitor 158 to pass through the substrate 122 in the vertical direction (the Z direction), are arranged in the capacitor area CA. The end surface D1 of each of the plurality of isolation structures DSA in the sensor array area SA and the end surface D2 of each of the plurality of dummy isolation structures DSB in the capacitor area CA extend in the same plane as the backside surface 122B of the substrate 122, the isolation structure DSA in the sensor array area SA and the dummy isolation structure DSB in the capacitor area CA include the same material. Therefore, by minimizing the difference in polishing rate between the sensor array area SA and the capacitor area CA therearound when the substrate 122 is planarized up to the backside surface 122B of the substrate 122 during a fabrication process of the image sensor 100, process defects due to a step difference between the sensor array area SA and the capacitor area CA, for example, defects, such as the generation of a dishing phenomenon in the capacitor area, may be suppressed. In addition, during the fabrication process of the image sensor 100, after a process of planarizing the substrate 122 up to the backside surface 122B of the substrate 122, and when a photolithography process is performed, the deterioration in process efficiency due to the deterioration in depth of focus (DOF) may be prevented, the productivity in the fabrication process of the image sensor 100 may improve, and the product completeness may improve by improving the sensitivity and resolution of the image sensor 100.

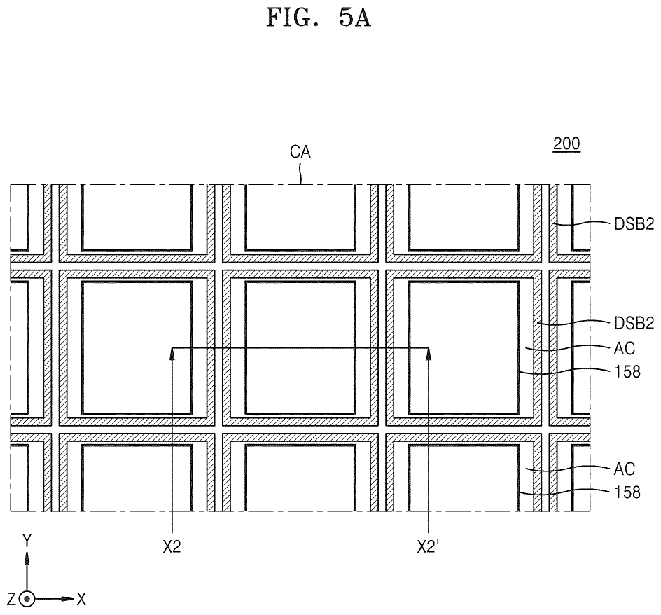

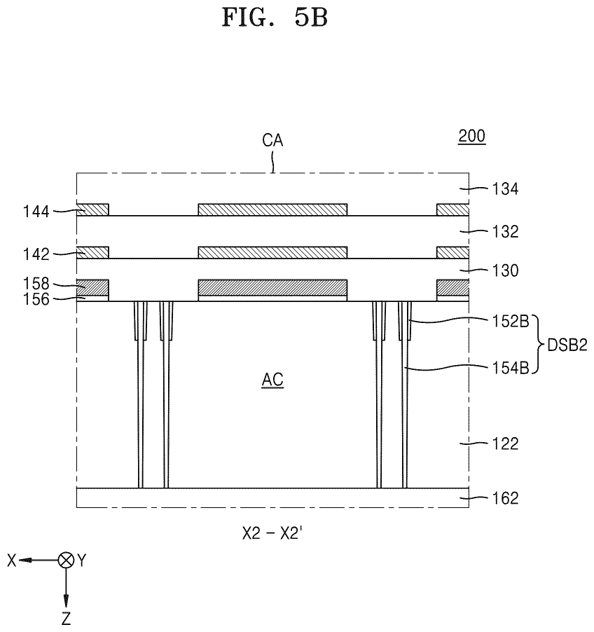

FIGS. 5A and 5B are diagrams illustrating an image sensor 200 according to one or more embodiments, and in particular, FIG. 5A is a plan view of a portion of the capacitor area CA, and FIG. 5B is a cross-sectional view of a portion of the capacitor area CA, taken along a line X2-X2′ of FIG. 5A. FIG. 5B illustrates components in a region of the image sensor 200, which corresponds to the region EX1 of FIG. 3. In FIGS. 5A and 5B, the same reference numerals as in FIGS. 1 to 4 respectively denote the same members, and here, repeated descriptions thereof are omitted.

Referring to FIGS. 5A and 5B, the image sensor 200 has substantially the same configuration as the image sensor 100 described with reference to FIGS. 1 to 4. However, the image sensor 200 includes a plurality of capacitors 158 arranged in the capacitor area CA, and a plurality of dummy isolation structures DSB2 arranged in the capacitor area CA to be each adjacent to a capacitor 158. The plurality of dummy isolation structures DSB2 may be arranged apart from each other in the first horizontal direction (the X direction) and the second horizontal direction (the Y direction).

In the image sensor 200, the plurality of capacitors 158 may be arranged in a line in each of the first horizontal direction (the X direction) and the second horizontal direction (the Y direction), which are parallel to the backside surface 122B of the substrate 122 and orthogonal to each other, and thus form a matrix. The plurality of capacitors 158 may be arranged apart from each other in the first horizontal direction (the X direction) and the second horizontal direction (the Y direction). In the image sensor 200, some of the plurality of capacitors 158 may be arranged in a line in the first horizontal direction (the X direction). Herein, a plurality of capacitors 158 arranged in a line in the first horizontal direction (the X direction), from among the plurality of capacitors 158, may each be referred to as a first capacitor. In the image sensor 200, some others of the plurality of capacitors 158 may be arranged in a line in the second horizontal direction (the Y direction). Herein, a plurality of capacitors 158 arranged in a line in the second horizontal direction (the Y direction), from among the plurality of capacitors 158, may each be referred to as a second capacitor.

Each of the plurality of dummy isolation structures DSB2 may have substantially the same configuration as the dummy isolation structure DSB described with reference to FIGS. 3 and 4. However, in the image sensor 200, two dummy isolation structures DSB2 may be arranged between two adjacent capacitors 158 from among the plurality of capacitors 158.

Each of the plurality of dummy isolation structures DSB2 may pass through, in the vertical direction (the Z direction), a portion of the substrate 122, which faces a separation space between two adjacent capacitors 158 from among the plurality of capacitors 158, such that the plurality of dummy isolation structures DSB2 does not respectively overlap the plurality of capacitors 158 in the vertical direction (the Z direction).

As shown in FIG. 5A, a plurality of dummy isolation structures DSB2 arranged in a line in the first horizontal direction (the X direction), from among the plurality of dummy isolation structures DSB2, may be separated from each other in the first horizontal direction (the X direction). Herein, the plurality of dummy isolation structures DSB2 arranged in a line in the first horizontal direction (the X direction) may each be referred to as a first dummy isolation structure. A plurality of dummy isolation structures DSB2 arranged in a line in the second horizontal direction (the Y direction), from among the plurality of dummy isolation structures DSB2, may be separated from each other in the second horizontal direction (the Y direction). Herein, the plurality of dummy isolation structures DSB2 arranged in a line in the second horizontal direction (the Y direction) may each be referred to as a second dummy isolation structure.

Each of the plurality of dummy isolation structures DSB2 may have a shape of a rectangular ring, which is horizontally separated from the capacitor 158 to surround the capacitor 158, when viewed in a plane (the X-Y plane in FIGS. 5A and 5B) that is parallel to the backside surface 122B of the substrate 122, and may be arranged around the capacitor 158 to pass through the substrate 122 in the vertical direction (the Z direction). The plurality of dummy isolation structures DSB2 may be arranged in a line in each of the first horizontal direction (the X direction) and the second horizontal direction (the Y direction) and thus form a matrix.

Each of the plurality of dummy isolation structures DSB2 may include a portion extending lengthwise in the second horizontal direction (the Y direction) in a local area of the substrate 122, which faces a separation space between two adjacent capacitors 158 from among the plurality of capacitors 158 arranged in a line in the first horizontal direction (the X direction). Each of the plurality of dummy isolation structures DSB2 may include a portion extending lengthwise in the first horizontal direction (the X direction) in a local area of the substrate 122, which faces a separation space between two adjacent capacitors 158 from among the plurality of capacitors 158 arranged in a line in the second horizontal direction (the Y direction).

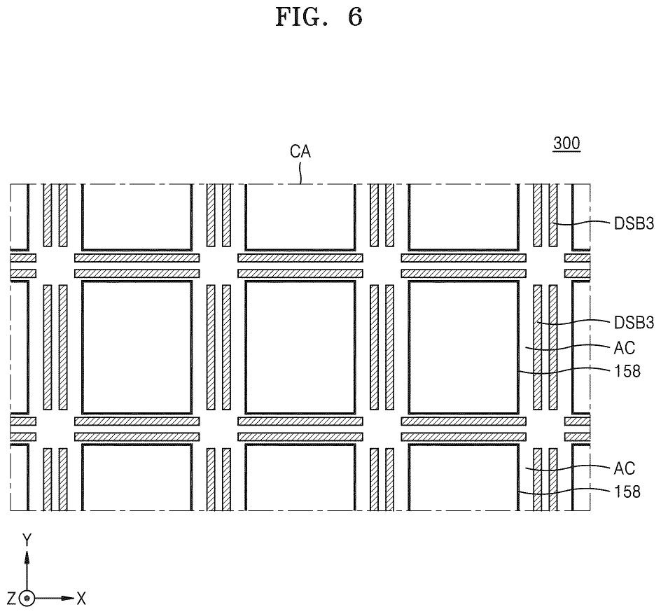

FIG. 6 is a plan view illustrating an image sensor 300 according to one or more embodiments. FIG. 6 illustrates a planar configuration of a portion of the capacitor area CA of the image sensor 300. In FIG. 6, the same reference numerals as in FIGS. 1 to 5 respectively denote the same members, and here, repeated descriptions thereof are omitted.

Referring to FIG. 6, the image sensor 300 has substantially the same configuration as the image sensor 200 described with reference to FIGS. 5A and 5B. However, the image sensor 300 includes a plurality of dummy isolation structures DSB3, which are each arranged adjacent to the capacitor 158, in the capacitor area CA. The plurality of dummy isolation structures DSB3 may be arranged apart from each other in the first horizontal direction (the X direction) and the second horizontal direction (the Y direction).

Each of the plurality of dummy isolation structures DSB3 may have substantially the same configuration as the dummy isolation structure DSB described with reference to FIGS. 3 and 4. However, in the image sensor 300, two dummy isolation structures DSB3 may be arranged between two adjacent capacitors 158 from among the plurality of capacitors 158.

A separation distance between two dummy isolation structures DSB3, which are arranged between two adjacent capacitors 158 in terms of the first horizontal direction (the X direction), from among the plurality of dummy isolation structures DSB3, may be less than a separation distance between two dummy isolation structures DSB3, which are separated from each other in the first horizontal direction (the X direction) with one capacitor 158 therebetween. A separation distance between two dummy isolation structures DSB3, which are arranged between two adjacent capacitors 158 in terms of the second horizontal direction (the Y direction), from among the plurality of dummy isolation structures DSB3 may be less than a separation distance between two dummy isolation structures DSB3, which are separated from each other in the second horizontal direction (the Y direction) with one capacitor 158 therebetween.

Some dummy isolation structures DSB3 from among the plurality of dummy isolation structures DSB3 may each include a portion extending lengthwise in the second horizontal direction (the Y direction) in a local area of the substrate 122, which faces a separation space between two adjacent capacitors 158 from among the plurality of capacitors 158 arranged in a line in the first horizontal direction (the X direction). Some other isolation structures DSB3 from among the plurality of dummy isolation structures DSB3 may each include a portion extending lengthwise in the first horizontal direction (the X direction) in a local area of the substrate 122, which faces a separation space between two adjacent capacitors 158 from among the plurality of capacitors 158 arranged in a line in the second horizontal direction (the Y direction).

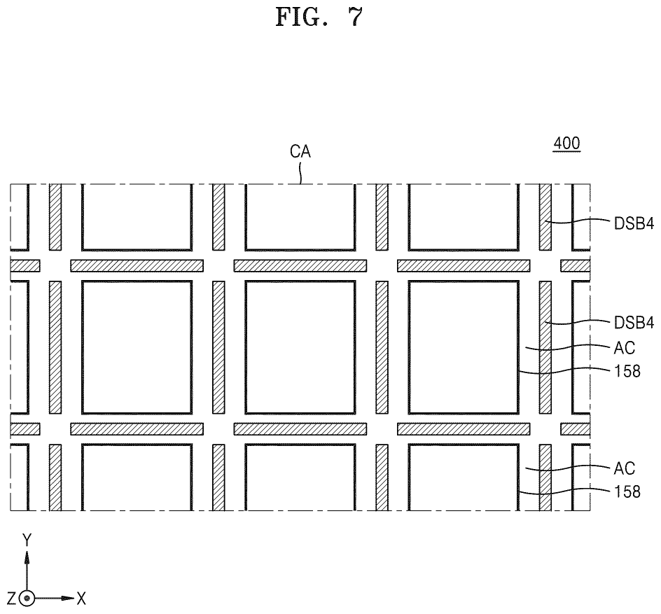

FIG. 7 is a plan view illustrating an image sensor 400 according to one or more embodiments. FIG. 7 illustrates a planar configuration of a portion of the capacitor area CA of the image sensor 400. In FIG. 7, the same reference numerals as in FIGS. 1 to 5 respectively denote the same members, and here, repeated descriptions thereof are omitted.

Referring to FIG. 7, the image sensor 400 has substantially the same configuration as the image sensor 200 described with reference to FIGS. 5A and 5B. However, the image sensor 400 includes a plurality of dummy isolation structures DSB4, which are each arranged adjacent to the capacitor 158, in the capacitor area CA. The plurality of dummy isolation structures DSB4 may be arranged apart from each other in the first horizontal direction (the X direction) and the second horizontal direction (the Y direction).

Each of the plurality of dummy isolation structures DSB4 may have substantially the same configuration as the dummy isolation structure DSB described with reference to FIGS. 3 and 4. However, in the image sensor 400, one dummy isolation structure DSB4 may be arranged between two adjacent capacitors 158 from among the plurality of capacitors 158.

Some of the plurality of dummy isolation structures DSB4 may be arranged in a line in the first horizontal direction (the X direction) to be separate from each other in the first horizontal direction (the X direction). Herein, a plurality of dummy isolation structures DSB4 arranged in a line in the first horizontal direction (the X direction) to be separate from each other in the first horizontal direction (the X direction), from among the plurality of dummy isolation structures DSB4, may each be referred to as a first dummy isolation structure. Some others of the plurality of dummy isolation structures DSB4 may be arranged in a line in the second horizontal direction (the Y direction) to be separate from each other in the second horizontal direction (the Y direction). Herein, a plurality of dummy isolation structures DSB4 arranged in a line in the second horizontal direction (the Y direction) to be separate from each other in the second horizontal direction (the Y direction), from among the plurality of dummy isolation structures DSB4, may each be referred to as a second dummy isolation structure.

The first dummy isolation structures from among the plurality of dummy isolation structures DSB4 may each be arranged one-by-one between two capacitors 158, which are selected from the plurality of capacitors 158 and adjacent to each other in the second horizontal direction (the Y direction), and may each have a shape of a first line linearly extending lengthwise in the first horizontal direction (the X direction).

The second dummy isolation structures from among the plurality of dummy isolation structures DSB4 may each be arranged one-by-one between two capacitors 158, which are selected from the plurality of capacitors 158 and adjacent to each other in the first horizontal direction (the Y direction), and may each have a shape of a second line linearly extending lengthwise in the second horizontal direction (the Y direction). The first line may be orthogonal to the second line.

In one or more embodiments, a separation distance in the first horizontal direction (the X direction) between the plurality of dummy isolation structures DSB4 arranged in a line in the first horizontal direction (the X direction) may be constant. In one or more embodiments, a separation distance in the second horizontal direction (the Y direction) between the plurality of dummy isolation structures DSB4 arranged in a line in the second horizontal direction (the Y direction) may be constant.

Each of the image sensors 200, 300, and 400 described with reference to FIGS. 5A, 5B, 6, and 7 includes the capacitor area CA, which is located adjacent to the sensor array area SA to surround at least a portion of the sensor array area SA, and the plurality of dummy isolation structures DSB2, DSB3, and DSB4 are each arranged in the capacitor area CA such that each dummy isolation structure DSB2, DSB3, or DSB4 is located adjacent to the capacitor 158 to pass through the substrate 122 in the vertical direction (the Z direction). An end surface of each of the plurality of dummy isolation structures DSB2, DSB3, and DSB4 and the end surface D1 (see FIG. 3) of each of the plurality of isolation structures DSA in the sensor array area SA extend in the same plane as the backside surface 122B of the substrate 122, and each of the plurality of dummy isolation structures DSB2, DSB3, and DSB4 and the isolation structure DSA in the sensor array area SA include the same material. Therefore, by minimizing the difference in polishing rate between the sensor array area SA and the capacitor area CA therearound when the substrate 122 is planarized up to the backside surface 122B of the substrate 122 during a fabrication process of each of the image sensors 200, 300, and 400, process defects due to a step difference between the sensor array area SA and the capacitor area CA, for example, defects, such as the generation of a dishing phenomenon in the capacitor area CA, may be suppressed. In addition, during the fabrication process of each of the image sensors 200, 300, and 400, after a process of planarizing the substrate 122 up to the backside surface 122B of the substrate 122, and when a photolithography process is performed, the deterioration in process efficiency due to the deterioration in DOF may be prevented, the productivity in the fabrication process of each of the image sensors 200, 300, and 400 may improve, and the product completeness may improve by improving the sensitivity and resolution of each of the image sensors 200, 300, and 400.

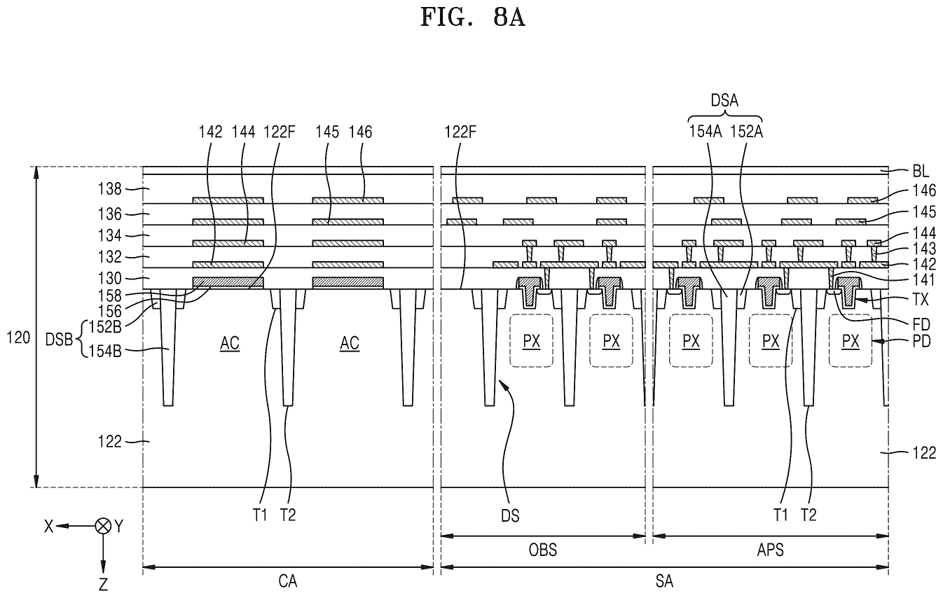

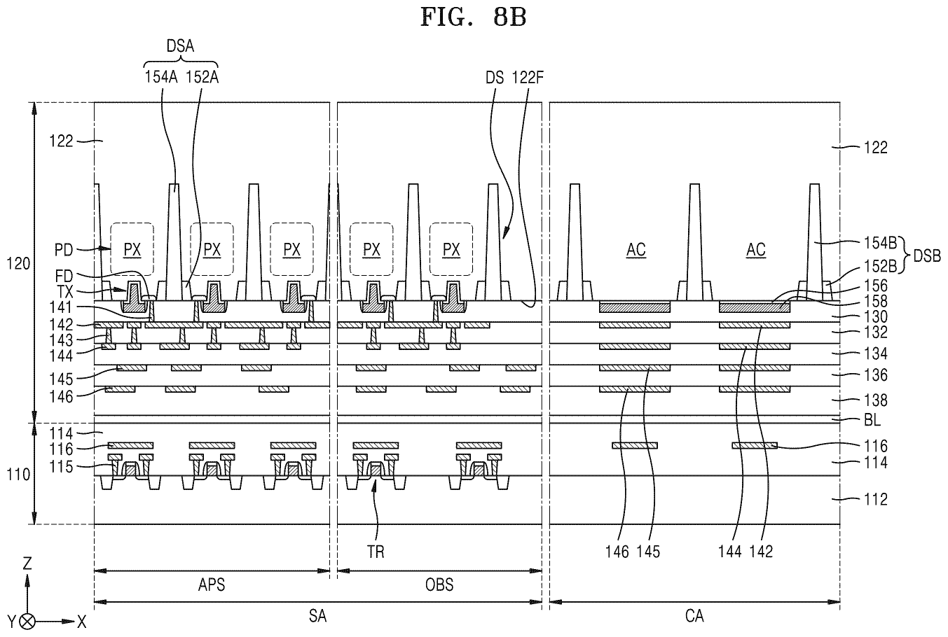

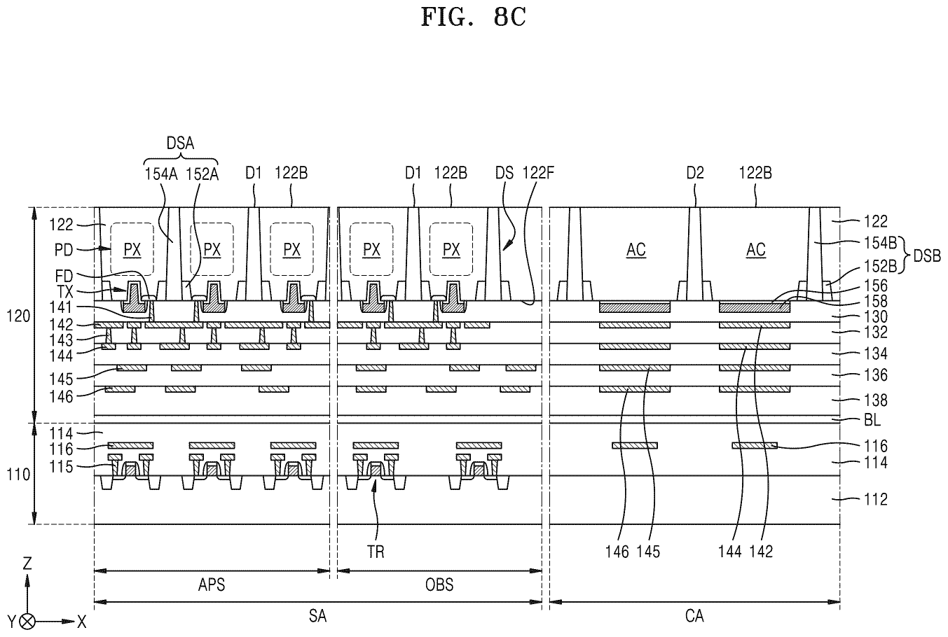

FIGS. 8A to 8C are cross-sectional views respectively illustrating a sequence of processes of a method of fabricating an image sensor, according to one or more embodiments. An example of a method of fabricating the image sensor 100 shown in FIGS. 3 and 4 is described with reference to FIGS. 8A to 8C. In FIGS. 8A to 8C, the same reference numerals as in FIGS. 1 to 4 respectively denote the same members, and here, repeated descriptions thereof are omitted.

Referring to FIG. 8A, the substrate 122 is prepared, followed by forming a plurality of shallow trenches T1 by partially etching the substrate 122 from the frontside surface 122F of the substrate 122 in the sensor array area SA and the capacitor area CA, and then, a plurality of local device isolation films 152A and 152B may be formed to respectively fill the plurality of shallow trenches T1. Next, a plurality of deep trenches T2 may be formed to each pass through a local device isolation film 152B and a portion of the substrate 122, and a plurality of main device isolation films 154A and 154B to respectively fill the plurality of deep trenches T2. As a result, a plurality of isolation structures DSA, which each include a local device isolation film 152A and a main device isolation film 154A, may be formed in the sensor array area SA, and a plurality of dummy isolation structures DSB, which each include a local device isolation film 152B and a main device isolation film 154B, may be formed in the capacitor area CA. In the capacitor area CA, a plurality of active regions AC may be defined by the plurality of dummy isolation structures DSB.

Next, ions may be implanted into the substrate 122 from the frontside surface 122F of the substrate 122 in the sensor array area SA, thereby forming a plurality of photodiodes PD in the sensor array area SA.

Next, a plurality of gate structures, which each include a transfer transistor TX including a gate dielectric film and a transfer gate, may be formed on the frontside surface 122F of the substrate 122 in the sensor array area SA, and a floating diffusion region FD may be formed by implanting impurity ions into a portion of the substrate 122 from the frontside surface 122F of the substrate 122. The plurality of gate structures may respectively include gate structures constituting transistors required to drive a plurality of unit pixels PX, which are included in the image sensor 100.

While the plurality of gate structures each including the transfer transistor TX are formed in the sensor array area SA, a plurality of insulating films 156 and a plurality of capacitors 158 may be formed on the frontside surface 122F of the substrate 122 in the capacitor area CA.

Next, in the sensor array area SA and the capacitor area CA, a plurality of interlayer dielectrics 130, 132, 134, 136, and 138 may be formed to cover the plurality of gate structures, which each include the transfer transistor TX, and the plurality of capacitors 158, and a wiring structure including a plurality of via contacts 141 and 143 and a plurality of wiring layers 142, 144, 145, and 146 may be formed. Next, a bonding layer BL may be formed on an interlayer dielectric 138, which is externally exposed, in the wiring structure.

Referring to FIG. 8B, a first semiconductor chip 110 may be bonded onto the bonding layer BL, and the obtained resulting product may be rotated to cause the substrate 122 to face upwards in the vertical direction (the Z direction).

Referring to FIG. 8C, an exposed portion of the substrate 122, a portion of each of the plurality of isolation structures DSA, and a portion of each of the plurality of dummy isolation structures DSB, in the sensor array area SA and the capacitor area CA, may be removed by a mechanical grinding process, a chemical mechanical polishing (CMP) process, a wet-etching process, or a combination thereof, whereby the backside surface 122B of the substrate 122, the end surface D1 of each of the plurality of isolation structures DSA in the sensor array area SA, and the end surface D2 of each of the plurality of dummy isolation structures DSB in the capacitor area CA may extend in the same plane. Here, because the plurality of isolation structures DSA and the plurality of dummy isolation structures DSB, which have the same structure, are respectively formed in the sensor array area SA and the capacitor area CA, when the resulting product obtained by removing the portion of the substrate 122 is considered, the backside surface 122B of the substrate 122 may extend flat in each of the sensor array area SA and the capacitor area CA without generating process defects, such as an unintended dishing phenomenon, in the capacitor area CA.

Next, as shown in FIG. 3, a backside insulating film 162 may be formed on the backside surface 122B of the substrate 122, the end surface D1 of each of the plurality of isolation structures DSA, and the end surface D2 of each of the plurality of dummy isolation structures DSB. Next, a plurality of grid patterns 164, a first protective film 166, and a plurality of color filters 170 may be formed on or over the backside insulating film 162 in the active pixel sensor area APS, and a backside metal layer BML and a color filter 170B may be formed on or over the backside insulating film 162 in the optical black sensor area OBS and the capacitor area CA. Next, a microlens 180 and a second protective film 182 may be formed on or over each of the plurality of color filters 170 in the active pixel sensor area APS and a third protective film 180B and a fourth protective film 182B may be formed on or over the color filter 170B in the optical black sensor area OBS and the capacitor area CA, thereby fabricating the image sensor 100 described with reference to FIGS. 1 to 4.

Heretofore, although the example of the method of fabricating the image sensor 100 described with reference to FIGS. 1 to 4 has been described with reference to FIGS. 8A to 8C, it will be understood by those of ordinary skill in the art that the image sensors 200, 300, and 400 described with reference to FIGS. 5A, 5B, 6, and 7 and image sensors having various structures changed and modified therefrom may be fabricated by making various modifications and changes to the example described with reference to FIGS. 8A to 8C without departing from the spirit and scope of the disclosure.

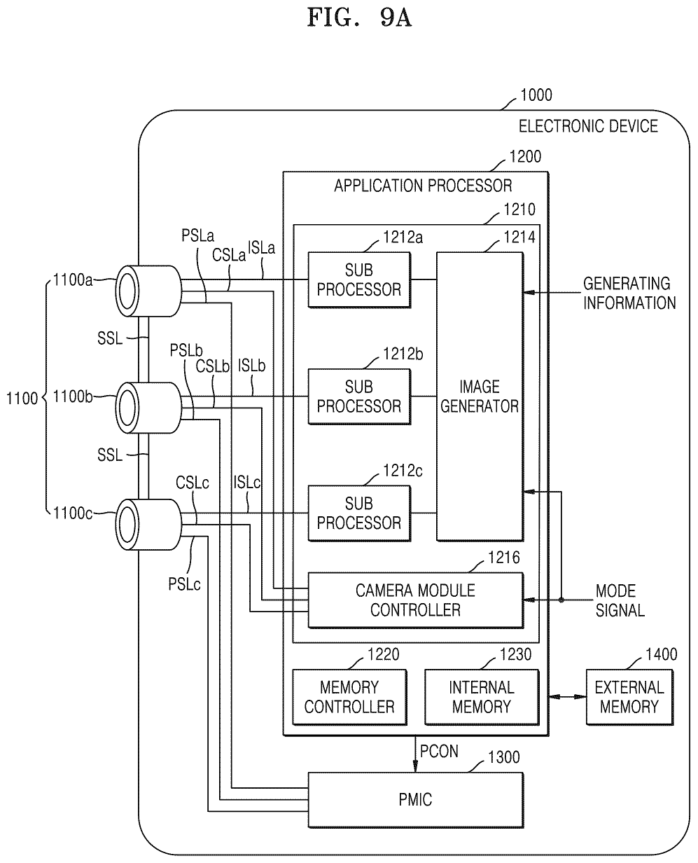

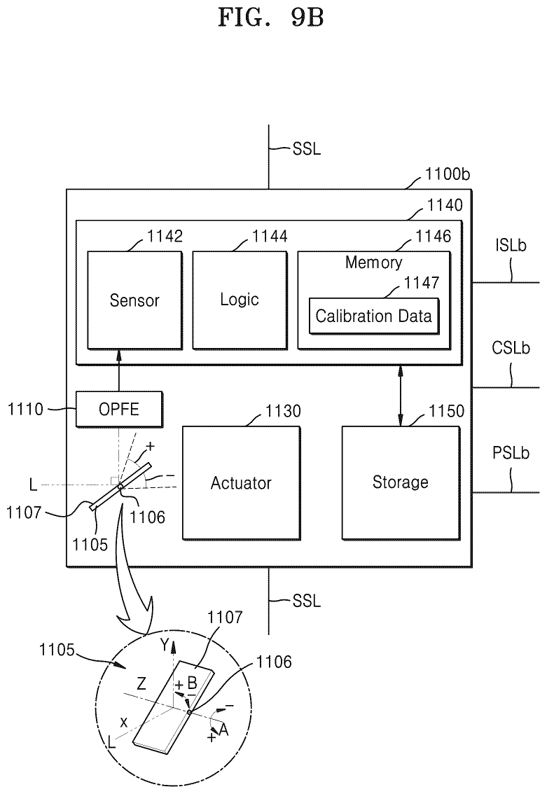

FIG. 9A is a block diagram of an electronic system according to one or more embodiments, and FIG. 9B is a detailed block diagram of a camera module of the electronic system of FIG. 9A.

Referring to FIG. 9A, the electronic system 1000 may include a camera module group 1100, an application processor 1200, a power management integrated circuit (PMIC) 1300, and an external memory 1400.

The camera module group 1100 may include a plurality of camera modules 1100a, 1100b, and 1100c. Although FIG. 9A illustrates an example in which three camera modules 1100a, 1100b, and 1100c are arranged, the disclosure is not limited thereto. In one or more embodiments, the camera module group 1100 may be modified to include only two camera modules. In addition, in one or more embodiments, the camera module group 1100 may be modified to include n camera modules (where n is a natural number of 4 or more).

Although a detailed configuration of the camera module 1100b is more specifically described below with reference to FIG. 9B, the following description may also be applied to the other camera modules 1100a and 1100c depending on embodiments.

Referring to FIG. 9B, the camera module 1100b may include a prism 1105, an optical path folding element (OPFE) 1110, an actuator 1130, an image sensing device 1140, and a storage 1150.

The prism 1105 may include a reflective surface 1107 of a light reflecting material and thus change the path of light L incident from outside the camera module 1100b.

In one or more embodiments, the prism 1105 may change the path of light L incident in a first direction (the X direction in FIG. 9B) into a second direction (the Y direction in FIG. 9B) that is perpendicular to the first direction. In addition, the prism 1105 may rotate the reflective surface 1107 of the light reflecting material in an A direction around a central shaft 1106 or rotate the central shaft 1106 in a B direction to change the path of light L incident in the first direction (the X direction) into the second direction (the Y direction) that is perpendicular to the first direction (the X direction). Here, the OPFE 1110 may also move in a third direction (the Z direction in FIG. 9B) that is perpendicular to the first direction (the X direction) and the second direction (the Y direction).

In one or more embodiments, as shown in FIG. 9B, an A-direction maximum rotation angle of the prism 1105 may be about 15 degrees or less in a plus (+) A direction and greater than about 15 degrees in a minus (−) A direction, but the disclosure is not limited thereto.

In one or more embodiments, the prism 1105 may move in a plus (+) or minus (−) B direction by as much as an angle of about 20 degrees, about 10 degrees to about 20 degrees, or about 15 degrees to about 20 degrees, and here, an angle by which the prism 1105 moves in the plus (+) B direction may be equal or similar, within a difference of about 1 degree, to an angle by which the prism 1105 moves in the minus (−) B direction.

In one or more embodiments, the prism 1105 may move the reflective surface 1107 of the light reflecting material in the third direction (for example, the Z direction) that is parallel to an extension direction of the central shaft 1106.

The OPFE 1110 may include, for example, m optical lenses (where m is a natural number). The m lenses may move in the second direction (the Y direction) and change an optical zoom ratio of the camera module 1100b. For example, assuming that the default optical zoom ratio of the camera module 1100b is Z, when the m optical lenses of the OPFE 1110 are moved, the optical zoom ratio of the camera module 1100b may be changed to 3Z or 5Z or greater.

The actuator 1130 may move the OPFE 1110 or an optical lens to a certain position. For example, the actuator 1130 may adjust the position of the optical lens such that an image sensor 1142 is positioned at a focal length of the optical lens for accurate sensing.

The image sensing device 1140 may include the image sensor 1142, a control logic 1144, and a memory 1146. The image sensor 1142 may sense an image of an object by using light L provided through the optical lens. The control logic 1144 may control overall operations of the camera module 1100b. For example, the control logic 1144 may control the operation of the camera module 1100b according to a control signal provided through a control signal line CSLb.

The memory 1146 may store information, such as calibration data 1147, required for the operation of the camera module 1100b. The calibration data 1147 may include information, which is necessary for the camera module 1100b to generate image data by using light L provided from outside the camera module 1100b. For example, the calibration data 1147 may include information about the degree of rotation, information about a focal length, information about an optical axis, or the like. When the camera module 1100b is implemented as a multi-state camera that has a focal length varying with the position of the optical lens, the calibration data 1147 may include a value of a focal length for each position (or each state) of the optical lens and information about auto-focusing.

The storage 1150 may store image data sensed by the image sensor 1142. The storage 1150 may be arranged outside the image sensing device 1140 and may be implemented in a stacked from with a sensor chip constituting the image sensing device 1140. In one or more embodiments, although the storage 1150 may include electrically erasable programmable read-only memory (EEPROM), the disclosure is not limited thereto.

The image sensor 1142 may include the image sensor 100, 200, 300, or 400 described with reference to FIGS. 1 to 7 or an image sensor variously modified and changed therefrom without departing from the scope of the disclosure.

Referring to FIGS. 9A and 9B, in one or more embodiments, each of the camera modules 1100a, 1100b, and 1100c may include the actuator 1130. Accordingly, the camera modules 1100a, 1100b, and 1100c may include the calibration data 1147, which is the same or different according to the operation of the actuator 1130 in each of the camera modules 1100a, 1100b, and 1100c.

In one or more embodiments, one camera module (for example, 1100b) from among the plurality of camera modules 1100a, 1100b, and 1100c may be of a folded-lens type including the prism 1105 and the OPFE 1110 as described above, and the other camera modules (for example, 1100a and 1100c) may be of a vertical type not including the prism 1105 and the OPFE 1110, but the disclosure is not limited thereto.

In one or more embodiments, one camera module (for example, 1100c) from among the plurality of camera modules 1100a, 1100b, and 1100c may include, for example, a vertical depth camera, which extracts depth information by using an infrared (IR) ray. In this case, the application processor 1200 may generate a three-dimensional (3D) depth image by merging image data provided from the depth camera with image data provided from another camera module (for example, 1100a or 1100b).

In one or more embodiments, at least two camera modules (for example, 1100a and 1100b) from among the plurality of camera modules 1100a, 1100b, and 1100c may respectively have different field-of-views. In this case, for example, the two camera modules (for example, 1100a and 1100b) from among the plurality of camera modules 1100a, 1100b, and 1100c may respectively have different optical lenses, but the disclosure is not limited thereto.

In addition, in one or more embodiments, the plurality of camera modules 1100a, 1100b, and 1100c may respectively have different field-of-views. In this case, the plurality of camera modules 1100a, 1100b, and 1100c may respectively include different optical lenses, but the disclosure is not limited thereto.

In one or more embodiments, the plurality of camera modules 1100a, 1100b, and 1100c may be physically separated from one another. That is, a sensing region of one image sensor 1142 is not divided and used by the plurality of camera modules 1100a, 1100b, and 1100c, but the image sensor 1142 may be independently included in each of the plurality of camera modules 1100a, 1100b, and 1100c.

Referring again to FIG. 9A, the application processor 1200 may include an image processing unit 1210, a memory controller 1220, and an internal memory 1230. The application processor 1200 may be implemented separately from the plurality of camera modules 1100a, 1100b, and 1100c. For example, the application processor 1200 and the plurality of camera modules 1100a, 1100b, and 1100c may be implemented by separate semiconductor chips from each other.

The image processing unit 1210 may include a plurality of sub-processors 1212a, 1212b, and 1212c, an image generator 1214, and a camera module controller 1216. The image processing unit 1210 may include as many sub-processors 1212a, 1212b, and 1212c as the camera modules 1100a, 1100b, and 1100c.

Pieces of image data respectively generated by the camera modules 1100a, 1100b, and 1100c may be respectively provided to the sub-processors 1212a, 1212b, and 1212c corresponding thereto through image signal lines ISLa, ISLb, and ISLc separated from each other. For example, image data generated by the camera module 1100a may be provided to the sub-processor 1212a through the image signal line ISLa, image data generated by the camera module 1100b may be provided to the sub-processor 1212b through the image signal line ISLb, and image data generated by the camera module 1100c may be provided to the sub-processor 1212c through the image signal line ISLc. Such image data transmission may be performed by using, for example, a mobile industry processor interface (MIPI)-based camera serial interface (CSI), but the disclosure is not limited thereto.

In one or more embodiments, a single sub-processor may be provided to correspond to a plurality of camera modules. For example, the sub-processors 1212a and 1212c may not be separated as shown in FIG. 9A but may be integrated into a single sub-processor, and the image data provided from the camera module 1100a or the camera module 1100c may be selected by a selection element (for example, a multiplexer) and then provided to the integrated sub-processor.

The image data provided to each of the sub-processors 1212a, 1212b, and 1212c may be provided to the image generator 1214. The image generator 1214 may generate an output image by using the image data provided from each of the sub-processors 1212a, 1212b, and 1212c according to image generating information or a mode signal.

Specifically, the image generator 1214 may generate the output image by merging at least portions of pieces of image data, which are respectively generated by the camera modules 1100a, 1100b, and 1100c having different field-of-views, according to the image generating information or the mode signal. In addition, the image generator 1214 may generate the output image by selecting one of the pieces of image data, which are respectively generated by the camera modules 1100a, 1100b, and 1100c having different field-of-views, according to the image generating information or the mode signal.

In one or more embodiments, the image generating information may include a zoom signal or a zoom factor. In addition, in one or more embodiments, the mode signal may be based on a mode selected by a user.

When the image generating information includes a zoom signal or a zoom factor and the camera modules 1100a, 1100b, and 1100c respectively have different field-of-views, the image generator 1214 may perform different operations depending on the types of zoom signals. For example, when the zoom signal is a first signal, the image generator 1214 may merge image data output from the camera module 1100a and image data output from the camera module 1100c and then generate an output image by using a merged image signal and image data that is output from the camera module 1100b and not used for merging. When the zoom signal is a second signal that is different from the first signal, the image generator 1214 may generate an output image by selecting one of the pieces of image data respectively output from the camera modules 1100a, 1100b, and 1100c, instead of performing such merging of image data. However, the disclosure is not limited thereto, and a method of processing image data may be changed without limitation, as needed.

In one or more embodiments, the image generator 1214 may receive a plurality of pieces of image data, which have different exposure times, from at least one of the plurality of sub-processors 1212a, 1212b, and 1212c and perform high dynamic range (HDR) processing on the plurality of pieces of image data, thereby generating merged image data having an increased dynamic range.

The camera module controller 1216 may provide a control signal to each of the camera modules 1100a, 1100b, and 1100c. A control signal generated by the camera module controller 1216 may be provided to a corresponding one of the camera modules 1100a, 1100b, and 1100c through a corresponding one of control signal lines CSLa, CSLb, and CSLc, which are separated from each another.

One camera module, for example, the camera module 1100b, from among the plurality of camera modules 1100a, 1100b, and 1100c may be designated as a master camera according to the mode signal or the image generating signal including a zoom signal, and the other camera modules, for example, the camera modules 1100a and 1100c may be designated as slave cameras. Such designation information may be included in a control signal and provided to each of the camera modules 1100a, 1100b, and 1100c through a corresponding one of the control signal lines CSLa, CSLb, and CSLc, which are separated from one another.

A camera module operating as a master or a slave may be changed according to a zoom factor or an operation mode signal. For example, when the field-of-view of the camera module 1100a is greater than that of the camera module 1100b and the zoom factor indicates a low zoom ratio, the camera module 1100b may operate as a master and the camera module 1100a may operate as a slave. In contrast, when the zoom factor indicates a high zoom ratio, the camera module 1100a may operate as a master and the camera module 1100b may operate as a slave.

In one or more embodiments, a control signal provided from the camera module controller 1216 to each of the camera modules 1100a, 1100b, and 1100c may include a sync enable signal. For example, when the camera module 1100b is a master camera and the camera modules 1100a and 1100c are slave cameras, the camera module controller 1216 may transmit the sync enable signal to the camera module 1100b. The camera module 1100b receiving the sync enable signal may generate a sync signal based on the received sync enable signal and may provide the generated sync signal to the camera modules 1100a and 1100c through a sync signal line SSL. The camera modules 1100a, 1100b, and 1100c may be synchronized with the sync signal and may transmit image data to the application processor 1200.

In one or more embodiments, a control signal provided from the camera module controller 1216 to each of the plurality of camera modules 1100a, 1100b, and 1100c may include mode information according to the mode signal. Each of the plurality of camera modules 1100a, 1100b, and 1100c may operate in a first operation mode or a second operation mode in relation to a sensing speed, based on the mode information.

In the first operation mode, each of the plurality of camera modules 1100a, 1100b, and 1100c may generate an image signal at a first speed (for example, at a first frame rate), encode the image signal at a second speed that is higher than the first speed (for example, at a second frame rate that is higher than the first frame rate), and transmit the encoded image signal to the application processor 1200. Here, the second speed may be 30 times or less the first speed.

The application processor 1200 may store the received image signal, for example, the encoded image signal, in the internal memory 1230 therein or in the external memory 1400 outside the application processor 1200. Next, the application processor 1200 may read the encoded image signal from the internal memory 1230 or the external memory 1400, decode the encoded image signal, and display image data generated based on the decoded image signal. For example, a corresponding one of the plurality of sub-processors 1212a, 1212b, and 1212c of the image processing unit 1210 may perform the decoding and may also perform image processing on the decoded image signal.

In the second operation mode, each of the plurality of camera modules 1100a, 1100b, and 1100c may generate an image signal at a third speed that is lower than the first speed (for example, at a third frame rate that is lower than the first frame rate) and transmit the image signal to the application processor 1200. The image signal provided to the application processor 1200 may not have been encoded. The application processor 1200 may perform image processing on the image signal, which is received, or may store the image signal in the internal memory 1230 or the external memory 1400.

The PMIC 1300 may provide power, for example, a power supply voltage, to each of the plurality of camera modules 1100a, 1100b, and 1100c. For example, under the control of the application processor 1200, the PMIC 1300 may provide first power to the camera module 1100a through a power signal line PSLa, provide second power to the camera module 1100b through a power signal line PSLb, and provide third power to the camera module 1100c through a power signal line PSLc.

The PMIC 1300 may generate power corresponding to each of the plurality of camera modules 1100a, 1100b, and 1100c and adjust the level of the power, in response to a power control signal PCON from the application processor 1200. The power control signal PCON may include a power adjustment signal for each operation mode of the plurality of camera modules 1100a, 1100b, and 1100c. For example, the operation mode may include a low-power mode, and in this case, the power control signal PCON may include information about a camera module to operate in the low-power mode and about a power level to be set. The levels of power respectively provided to the plurality of camera modules 1100a, 1100b, and 1100c may be equal or different. In addition, the level of power may be dynamically changed.

While the disclosure has been particularly shown and described with reference to embodiments thereof, it will be understood that various changes in form and details may be made therein without departing from the spirit and scope of the following claims.

What is claimed is:

1. An image sensor comprising:
a sensor array area comprising:
a plurality of unit pixels each comprising a photodiode in a substrate, wherein the substrate comprises a frontside surface and a backside surface; and
at least one isolation structure passing through the substrate in a vertical direction from the frontside surface to the backside surface, wherein the at least one isolation structure isolates the plurality of unit pixels from one another; and
a capacitor area adjacent to the sensor array area, wherein the capacitor area comprises:
at least one capacitor on the frontside surface; and
at least one dummy isolation structure adjacent to the at least one capacitor, wherein the at least one dummy isolation structure passes through the substrate in the vertical direction,
wherein one end surface of each of the at least one isolation structure and the at least one dummy isolation structure extends in a same plane as the backside surface, and
wherein the at least one isolation structure and the at least one dummy isolation structure comprise a same material.

2. The image sensor of claim 1, wherein each of the at least one isolation structure and the at least one dummy isolation structure further comprises:
a main device isolation film passing through the substrate in the vertical direction from the frontside surface to the backside surface; and
a local device isolation film passing through a portion of the substrate in the vertical direction from the frontside surface and covering a portion of a sidewall of the main device isolation film adjacent to the frontside surface.

3. The image sensor of claim 1, wherein the sensor array area is in an area defined by the capacitor area.

4. The image sensor of claim 1,
wherein the at least one capacitor comprises a plurality of first capacitors arranged in a line in a first horizontal direction parallel to the backside surface, and
wherein the at least one dummy isolation structure comprises a portion extending lengthwise in a second horizontal direction in a local area of the substrate, the local area facing a separation space between two adjacent first capacitors from among the plurality of first capacitors, and the second horizontal direction being parallel to the backside surface and orthogonal to the first horizontal direction.

5. The image sensor of claim 1,
wherein the at least one capacitor comprises a plurality of capacitors arranged in a matrix comprising a line in a first horizontal direction and a line in a second horizontal direction, the first horizontal direction and the second horizontal direction being parallel to the backside surface and orthogonal to each other, and
wherein the at least one dummy isolation structure comprises a plurality of dummy isolation structures each passing through, in the vertical direction, a portion of the substrate facing a separation space between two adjacent capacitors from among the plurality of capacitors, such that the plurality of dummy isolation structures do not overlap the plurality of capacitors in the vertical direction.

6. The image sensor of claim 1,
wherein the at least one capacitor comprises a plurality of capacitors separated from each other in a horizontal direction,
wherein the at least one dummy isolation structure comprises a plurality of dummy isolation structures arranged respectively around the plurality of capacitors, wherein the plurality of dummy isolation structures are separated from each other, and
wherein a shape of each of the plurality of dummy isolation structures comprises a rectangular ring, wherein each of the plurality of dummy isolation structures surrounds a capacitor from the plurality of capacitors.

7. The image sensor of claim 1,
wherein the at least one capacitor comprises a plurality of capacitors separated from each other in a horizontal direction,
wherein the at least one dummy isolation structure comprises a plurality of dummy isolation structures arranged respectively around the plurality of capacitors, wherein the plurality of dummy isolation structures are separated from each other, and
wherein a dummy isolation structure from among the plurality of dummy isolation structures is between two adjacent capacitors from among the plurality of capacitors.

8. The image sensor of claim 1,
wherein the at least one capacitor comprises a plurality of capacitors separated from each other in a horizontal direction,
wherein the at least one dummy isolation structure comprises a plurality of dummy isolation structures arranged respectively around the plurality of capacitors, wherein the plurality of dummy isolation structures are separated from each other, and
wherein two dummy isolation structures from among the plurality of dummy isolation structures are between two adjacent capacitors from among the plurality of capacitors.

9. An image sensor comprising:
a sensor array area comprising:
a plurality of unit pixels each comprising a photodiode in a substrate, wherein the substrate comprises a frontside surface and a backside surface; and
at least one isolation structure passing through the substrate in a vertical direction from the frontside surface to the backside surface, wherein the at least one isolation structure isolates the plurality of unit pixels from one another;
a pad area surrounding the sensor array area and comprising a plurality of conductive pads; and
a capacitor area between the sensor array area and the pad area, the capacitor area comprising:
a plurality of capacitors on the frontside surface; and
at least one dummy isolation structure passing through the substrate in the vertical direction between two adjacent capacitors from among the plurality of capacitors,
wherein one end surface of each of the at least one isolation structure and the at least one dummy isolation structure extends in a same plane as the backside surface, and
wherein the at least one isolation structure and the at least one dummy isolation structure comprise a same material.

10. The image sensor of claim 9,
wherein the capacitor area is closer to the sensor array area than to the pad area in a horizontal direction parallel to the backside surface, and
wherein the capacitor area surrounds at least a portion of the sensor array area.

11. The image sensor of claim 9,
wherein the plurality of capacitors comprise a plurality of first capacitors arranged in a line in a first horizontal direction parallel to the backside surface, and
wherein the at least one dummy isolation structure comprises a portion extending lengthwise in a second horizontal direction in a separation space between two adjacent first capacitors from among the plurality of first capacitors, the second horizontal direction being parallel to the backside surface and orthogonal to the first horizontal direction.

12. The image sensor of claim 9,
wherein the plurality of capacitors are arranged in a matrix comprising a line in a first horizontal direction and a line in a second horizontal direction, the first horizontal direction and the second horizontal direction being parallel to the backside surface and orthogonal to each other, and
wherein the at least one dummy isolation structure comprises a plurality of dummy isolation structures each passing through, in the vertical direction, a portion of the substrate facing a separation space between two adjacent capacitors from among the plurality of capacitors, such that the plurality of dummy isolation structures do not overlap the plurality of capacitors in the vertical direction.

13. The image sensor of claim 9,
wherein the at least one dummy isolation structure comprises a plurality of dummy isolation structures arranged respectively around the plurality of capacitors,
wherein each of the plurality of capacitors is on the frontside surface of the substrate, and
wherein a shape of each of the plurality of dummy isolation structures comprises a rectangular ring, and wherein each of the plurality of dummy isolation structures surrounds a capacitor from the plurality of capacitors.

14. The image sensor of claim 9,
wherein the at least one dummy isolation structure comprises a plurality of dummy isolation structures arranged respectively around the plurality of capacitors,
wherein the plurality of capacitors comprise a plurality of first capacitors arranged in a line in a first horizontal direction parallel to the backside surface, and
wherein the plurality of dummy isolation structures comprise a plurality of first dummy isolation structures arranged in a line in the first horizontal direction, wherein the plurality of first dummy isolation structures are separated from each other in the first horizontal direction.

15. The image sensor of claim 9,
wherein the plurality of capacitors are arranged in a matrix comprising a line in a first horizontal direction and a line in a second horizontal direction, the first horizontal direction and the second horizontal direction being parallel to the backside surface and orthogonal to each other,
wherein the at least one dummy isolation structure comprises a plurality of dummy isolation structures arranged respectively around the plurality of capacitors,
wherein the plurality of dummy isolation structures comprise a plurality of first dummy isolation structures arranged in a line in the first horizontal direction and a plurality of second dummy isolation structures arranged in a line in the second horizontal direction, wherein the plurality of first dummy isolation structures are separated from each other in the first horizontal direction, and the plurality of second dummy isolation structures are separated from each other in the second horizontal direction, and
wherein each of the plurality of first dummy isolation structures and each of the plurality of second dummy isolation structures is arranged between two capacitors from among the plurality of capacitors.

16. The image sensor of claim 15, wherein a shape of each of the plurality of first dummy isolation structures and each of the plurality of second dummy isolation structures comprises a rectangular ring surrounding a capacitor from the plurality of capacitors.

17. The image sensor of claim 15,
wherein each of the plurality of first dummy isolation structures is arranged between two capacitors from the plurality of capacitors, is adjacent to another first dummy isolation structure of the plurality of first dummy isolation structures in the second horizontal direction, and comprises a shape of a first line linearly extending lengthwise in the first horizontal direction, and
wherein each of the plurality of second dummy isolation structures is arranged between two capacitors selected from the plurality of capacitors, is adjacent to another second dummy isolation structure of the plurality of second dummy isolation structures in the first horizontal direction, and comprises a shape of a second line linearly extending lengthwise in the second horizontal direction.

18. An image sensor comprising:
a first semiconductor chip comprising a logic area and a peripheral circuit area, wherein the logic area comprises a logic device and the peripheral circuit area comprises a peripheral circuit; and
a second semiconductor chip stacked on the first semiconductor chip,
wherein the second semiconductor chip comprises:
a substrate comprising a frontside surface and a backside surface;
a sensor array area comprising:
a plurality of unit pixels each comprising a photodiode in the substrate; and
a plurality of isolation structures passing through the substrate in a vertical direction from the frontside surface to the backside surface and isolating the plurality of unit pixels from one another; and
a capacitor area surrounding the sensor array area and comprising:
a plurality of capacitors on the frontside surface; and
a plurality of dummy isolation structures arranged respectively adjacent to the plurality of capacitors and passing through the substrate in the vertical direction,
wherein one end surface of each of the plurality of isolation structures and the plurality of dummy isolation structures extends in a same plane as the backside surface, and
wherein the plurality of isolation structures and the plurality of dummy isolation structures comprise a same material.

19. The image sensor of claim 18,
wherein the sensor array area further comprises:
an active pixel sensor area comprising a plurality of active pixels; and
an optical black sensor area surrounding the active pixel sensor area and comprising a plurality of optical black pixels,
wherein the optical black sensor area is between the capacitor area and the active pixel sensor area, and wherein the capacitor area surrounds the active pixel sensor area and the optical black sensor area,
wherein the plurality of capacitors each overlap at least one wiring layer of the first semiconductor chip,
wherein the plurality of capacitors are arranged in matrix comprising a line in a first horizontal direction and a line in a second horizontal direction, the first horizontal direction and the second horizontal direction being parallel to the backside surface and orthogonal to each other, and
wherein the plurality of dummy isolation structures each pass through, in the vertical direction, a portion of the substrate which faces a separation space between two adjacent capacitors from among the plurality of capacitors.

20. An electronic system comprising:
at least one camera module comprising the image sensor according to claim 1;
at least one processor; and
at least one memory storing at least one instruction,
wherein the at least one instruction, when executed by the at least one processor, causes the at least one processor to process image data received from the at least one camera module.
